(19) United States
(12) Patent Application Publication
(10) Pub. No.: US 2011/0186861 A1
(43) Pub. Date: Aug. 4, 2011

(54) SEMICONDUCTOR DEVICE AND METHOD OF MANUFACTURING THE SAME

(75) Inventors: Rajesh Kumar MALHAN, Nagoya-city (JP); Masaaki KUZUHARA, Fukui-city (JP)

(73) Assignee: DENSO CORPORATION, Kariya-city, Aichi-pref. (JP)

(21) Appl. No.: 13/014,037

(22) Filed: Jan. 26, 2011

(30) Foreign Application Priority Data
Jan. 29, 2010 (JP) 2010-18747

(51) Int. Cl. H01L 29/12; H01L 29/812; H01L 21/338

(52) U.S. Cl. 257/77; 257/256; 438/167; 257/E29.317; 257/E29.068; 257/E21.45

(57) ABSTRACT

A semiconductor device having a JFET or a MESFET mainly includes a semiconductor substrate, a first conductivity type semiconductor channel layer on the substrate, a first conductivity type semiconductor layer on the channel layer, and an i-type sidewall layer on a sidewall of a recess that penetrates the semiconductor layer to divide the semiconductor layer into a source region and a drain region. The semiconductor layer has an impurity concentration greater than an impurity concentration of the channel layer. The semiconductor device further includes a second conductivity type gate region that is located on the channel layer in the recess and on the i-type sidewall layer. The gate region is spaced from the source region and the drain region by the i-type sidewall layer.

### CROSS REFERENCE TO RELATED APPLICATION

This application is based on and claims priority to Japanese Patent Application No. 2010-18747 filed on Jan. 29, 2010, the disclosure of which is incorporated herein by reference.

### FIELD OF THE INVENTION

The present invention relates to a semiconductor device having a JFET or a MESFET, in particular, made of a wideband gap semiconductor material such as silicon carbide. The present invention also relates to a method of manufacturing the semiconductor device.

### BACKGROUND OF THE INVENTION

FIG. 13 illustrates a cross-sectional view of a junction field-effect transistor (JFET) disclosed in U.S. Pat. No. 7,560,325. The JEFT is made of silicon carbide (SiC), which is a material suitable for achieving high frequency and high resistance to voltage breakdown. As shown in FIG. 13, a p conductivity type buffer layer J2 is formed on a silicon carbide substrate J1, an n conductivity type channel layer J3 is formed on the p conductivity type buffer layer J2, and an n conductivity type layer J4 is formed on the n conductivity type channel layer J3. A recess J5 extending from a surface of the n conductivity type layer J4 to the n conductivity type channel layer J3 is formed by etching the n conductivity type layer J4. A p conductivity type gate region J7 is formed in the recess J5 through a p conductivity type layer J6. A source electrode J9 and a drain electrode J10 are formed through a metal layer J8 in such a manner that the source electrode J9 and the drain electrode J10 are spaced from the p conductivity type gate region J7.

In the normally-on mode JFET disclosed in U.S. Pat. No. 7,560,325, the p conductivity type layer J6 surrounds the p conductivity type gate region J7 to prevent the p conductivity type gate region J7 from being in direct contact with the n conductivity type layer J4, thereby preventing a PN junction with an abrupt concentration change. As a result, since a capacitance between the p conductivity type gate region J7 and the n conductivity type layer J4, i.e., a gate-source capacitance and a gate-drain capacitance are increased, it is difficult for the JFET to achieve high frequency. In addition, since the JFET is designed in such a manner that the n conductivity type channel layer J3 is pinched off by a depletion layer extending from the p conductivity type layer J6 having a lower concentration, application of a high voltage to the p conductivity type gate region J7 is required to turn off the JFET.

The above discussion regarding the capacitance increase can be applied to a metal-semiconductor field-effect transistor (MESFET).

In view of the above, it is an object of the present invention to provide a semiconductor device having a JFET or a MESFET with a structure for reducing a gate-source capacitance and a gate-drain capacitance. It is another object of the present invention to provide a method of manufacturing the semiconductor device.

### SUMMARY OF THE INVENTION

According to a first aspect of the present invention, a semiconductor device having a JFET includes a semiconductor substrate, a first conductivity type semiconductor channel layer, a first conductivity type semiconductor layer, a recess, an i-type sidewall layer, a second conductivity type gate region, a gate electrode, a source electrode, and a drain electrode. The channel layer is located on a main surface of the substrate. The semiconductor layer is located on a surface of the channel layer and has an impurity concentration greater than an impurity concentration of the channel layer. The recess penetrates the semiconductor layer to divide the semiconductor layer into a source region and a drain region. The i-type sidewall layer is located on a sidewall of the recess. The gate region is located on the surface of the channel layer in the recess and on a surface of the i-type sidewall layer. The gate region is spaced by the i-type sidewall layer from the source region and the drain region. The gate electrode is electrically connected to the gate region. The source electrode is electrically connected to the source region. The drain electrode is electrically connected to the drain region.

According to a second aspect of the present invention, a semiconductor device having a MESFET includes a semiconductor substrate, a first conductivity type semiconductor channel layer, a first conductivity type semiconductor layer, a recess, an i-type sidewall layer, a gate electrode, a source electrode, and a drain electrode. The channel layer is located on a main surface of the substrate. The semiconductor layer is located on a surface of the channel layer and has an impurity concentration greater than an impurity concentration of the channel layer. The recess penetrates the semiconductor layer to divide the semiconductor layer into a source region and a drain region. The i-type sidewall layer is located on a sidewall of the recess. The gate electrode is located on the surface of the channel layer in the recess and on a surface of the i-type sidewall layer to form a Schottky contact with the channel layer. The gate electrode is spaced by the i-type sidewall layer from the source region and the drain region. The source electrode is electrically connected to the source region. The drain electrode is electrically connected to the drain region.

According to a third aspect of the present invention, a method of manufacturing a semiconductor device having a JFET, includes preparing a semiconductor substrate, forming a first conductivity type semiconductor channel layer on a main surface the substrate by epitaxial growth, forming a first conductivity type semiconductor layer on a surface the channel layer by epitaxial growth in such a manner that the semiconductor layer has an impurity concentration greater than an impurity concentration of the channel layer, forming a recess by anisotropic etching of the semiconductor layer in such a manner that the recess penetrates the semiconductor layer to divide the semiconductor layer into a source region and a drain region, forming an i-type sidewall layer on a sidewall of the recess by epitaxial growth, forming a second conductivity type gate region on the surface of the channel layer in the recess and on a surface of the i-type sidewall layer by epitaxial growth in such a manner that the gate region is spaced by the i-type sidewall layer from the source region and the drain region, forming a gate electrode electrically connected to the gate region, forming a source electrode electrically connected to the source region, and forming a drain electrode electrically connected to the drain region.

According to a fourth aspect of the present invention, a method of manufacturing a semiconductor device having a MESFET includes preparing a semiconductor substrate, forming a first conductivity type semiconductor channel layer on a main surface the substrate by epitaxial growth, forming a first conductivity type semiconductor layer on a surface the channel layer by epitaxial growth in such a manner that the semiconductor layer has an impurity concentration greater than an impurity concentration of the channel layer, forming a recess by anisotropic etching of the semiconductor layer in such a manner that the recess penetrates the semiconductor layer to divide the semiconductor layer into a source region and a drain region, forming an i-type sidewall layer on a sidewall of the recess by epitaxial growth, forming a gate electrode on the surface of the channel layer in the recess and on a surface of the i-type sidewall layer in such a manner that the gate electrode forms a Schottky contact with the channel layer and is spaced by the i-type sidewall layer from the source region and the drain region, forming a source electrode electrically connected to the source region, and forming a drain electrode electrically connected to the drain region.

### BRIEF DESCRIPTION OF THE DRAWINGS

The above and other objectives, features and advantages of the present invention will become more apparent from the following detailed description made with check to the accompanying drawings. In the drawings:

FIG. 1 is a diagram illustrating a cross-sectional view of a SiC semiconductor device having a JFET according to a first embodiment of the present invention;

FIG. 2 is a diagram illustrating a cross-sectional view of a concrete example of the SiC semiconductor device of FIG. 1;

FIGS. 3A-3C are diagrams illustrating cross-sectional views of manufacturing processes of the SiC semiconductor device of FIG. 2;

FIGS. 4A-4C are diagrams illustrating cross-sectional views of manufacturing processes, following FIGS. 3A-3C, of the SiC semiconductor device of FIG. 2;

FIGS. 5A-5C are diagrams illustrating cross-sectional views of manufacturing processes, following FIGS. 4A-4C, of the SiC semiconductor device of FIG. 2;

FIGS. 6A-6C are diagrams illustrating cross-sectional views of manufacturing processes, following FIGS. 5A-5C, of the SiC semiconductor device of FIG. 2;

FIG. 7 is a diagram illustrating a cross-sectional view of a SiC semiconductor device having a JFET according to a second embodiment of the present invention;

FIGS. 8A-8C are diagrams illustrating cross-sectional views of manufacturing processes of the SiC semiconductor device of FIG. 7;

FIG. 9 is a diagram illustrating a cross-sectional view of a SiC semiconductor device having a JFET according to a third embodiment of the present invention;

FIG. 10 is a diagram illustrating a cross-sectional view of a SiC semiconductor device having a JFET according to a fourth embodiment of the present invention;

FIG. 11 is a diagram illustrating a cross-sectional view of a SiC semiconductor device having a MESFET according to a fifth embodiment of the present invention;

FIGS. 12A and 12B are diagrams illustrating cross-sectional views of manufacturing processes of the SiC semiconductor device of FIG. 11; and

FIG. 13 is a diagram illustrating a cross-sectional view of a conventional SiC semiconductor device having a JFET.

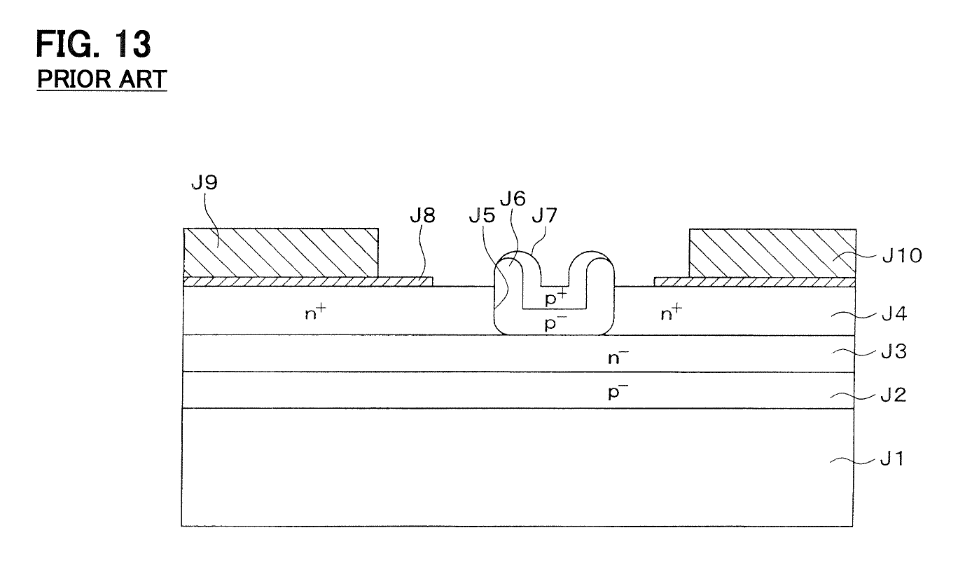

### DETAILED DESCRIPTION OF THE PREFERRED EMBODIMENTS

Embodiments of the present invention are described below with reference to the drawings. Throughout the embodiments, the same symbols are given to the same or corresponding parts in the drawings.

### First Embodiment

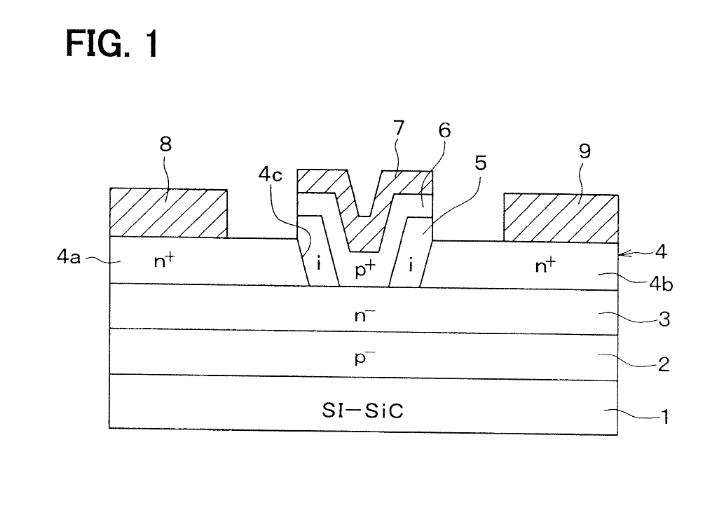

A first embodiment of the present invention is described below with reference to FIG. 1. FIG. 1 illustrates a cross-sectional view of a silicon carbide (SiC) semiconductor device having a JFET according to the first embodiment.

The SiC semiconductor device shown in FIG. 1 is formed by using a semi-insulating SiC substrate 1 having a main surface. The “semi-insulating” means that it is made of a non-doped semiconductor material and has a resistivity (or conductivity) closer to that of an insulating material. According to the first embodiment, the SiC substrate 1 can have a resistivity of from about 1×10¹⁰Ω·cm to about 1×10¹¹Ω·cm and a thickness of from about 50 μm to about 400 μm. For example, the SiC substrate 1 can have the thickness of about 350 μm. A p conductivity type buffer layer 2 is formed on the main surface of the SiC substrate 1. The p conductivity type buffer layer 2 can have an impurity concentration of from about 1×10¹⁶cm⁻³ to about 1×10¹⁷cm⁻³ and a thickness of from about 0.2 μm to about 2.0 μm. For example, the p conductivity type buffer layer 2 can have the impurity concentration of about 1×10¹⁶cm⁻³ and have the thickness of about 0.4 μm. The p conductivity type buffer layer 2 allows the SiC semiconductor device to have high resistance to voltage breakdown.

An n conductivity type channel layer 3 is formed on a surface of the p conductivity type buffer layer 2. The n conductivity type channel layer 3 provides a channel region. The n conductivity type channel layer 3 can have an impurity concentration of from about 1×10¹⁶cm⁻³ to about 1×10¹⁸cm⁻³ and a thickness of from about 0.1 μm to about 1.0 μm. For example, the n conductivity type channel layer 3 can have the impurity concentration of about 1×10¹⁷cm⁻³ and have the thickness of about 0.2 μm.

An n conductivity type layer 4 is formed on a surface of the n conductivity type channel layer 3. The n conductivity type layer 4 is divided in two regions by a recess 4c. The region of the n conductivity type layer 4 located on the left side in FIG. 1 with respect to the recess 4c serves as an n conductivity type source region 4a, and the region of the n conductivity type layer 4 located on the right side in FIG. 1 with respect to the recess 4c serves as an n conductivity type drain region 4b. Each of the n conductivity type source region 4a and the n conductivity type drain region 4b can have an impurity concentration of from about 5×10¹⁸cm⁻³to about 1×10²⁰cm⁻³ and a thickness of from about 0.1 μm to about 1.0 μm. For example, each of the n conductivity type source region 4a and the n conductivity type drain region 4b can have the impurity concentration of about 2×10¹⁹cm⁻³ and the thickness of about 0.4 μm.

The recess 4c extends from a surface of the n conductivity type layer 4 to the n conductivity type channel layer 3. Thus, the recess 4c penetrates the n conductivity type layer 4. A sidewall of the recess 4c can be parallel to a direction perpendicular to the surface of the substrate 1. Alternatively, the sidewall of the recess 4c can be slightly inclined with respect to the direction perpendicular to the surface of the substrate 1. In a case where the main surface of the substrate 1 is C-face (000-1) or Si-face (0001), the p conductivity type buffer layer 2, the n conductivity type channel layer 3, and the n conductivity type layer 4 are grown depending on the orientation of the main surface of the substrate 1. Therefore, the sidewall of the recess 4c is almost parallel to a-face plane.

An i (intrinsic)-type sidewall layer 5 is formed in the recess 4c so that a sidewall of the recess 4c can be covered with the i-type sidewall layer 5. The i-type sidewall layer 5 is made of i-type silicon carbide, which has a semi-insulating property. The i-type sidewall layer 5 can have an impurity concentration of from about 1×10¹¹cm⁻³ to about 1×10¹⁴cm⁻³ and a thickness of from about 0.1 μm to about 1.0 μm. For example, the i-type sidewall layer 5 can have the impurity concentration of about 1×10¹²cm⁻³ and the thickness of about 0.2 μm.

A p conductivity type gate region 6 is formed in the recess 4c so that the sidewall and a bottom of the recess 4c covered with the p conductivity type gate region 6. Specifically, in the recess 4c, the p conductivity type gate region 6 is formed on a surface of the n conductivity type channel layer 3 and a surface of the i-type sidewall layer 5. The p conductivity type gate region 6 is spaced by the i-type sidewall layer 5 from the n conductivity type source region 4a and the n conductivity type drain region 4b. The p conductivity type gate region 6 can have an impurity concentration of from about 5×10¹⁸cm⁻³ to about 5×10¹⁹cm⁻³ and a thickness of from about 0.1 μm to about 1.0 μm. For example, the p conductivity type gate region 6 can have the impurity concentration of about 1×10¹⁹cm⁻³ and the thickness of about 0.4 μm.

A gate electrode 7 is formed on a surface of the p conductivity type gate region 6. End surfaces (i.e., sidewalls) of the i-type sidewall layer 5, the p conductivity type gate region 6, and the gate electrode 7 are aligned with each other to from a continuous flat surface. The gate electrode 7 can have a multilayer structure. For example, the gate electrode 7 has a three-layer structure including a nickel-based (e.g., NiSi₂) metal layer forming ohmic contact with the p conductivity type gate region 6, a titanium-based metal layer on the nickel-based layer, and an aluminum layer or a gold layer on the titanium-based layer. The aluminum layer or the gold layer is electrically connected to a bonding wire or the like that is electrically connected to external circuitry. The nickel-based metal layer can have a thickness of from about 0.1 μm to about 0.5 μm, the titanium-based metal layer can have a thickness of from about 0.1 μm to about 0.5 μm, and the aluminum layer or the gold layer can have a thickness of from about 1.0 μm to about 5.0 μm. For example, the nickel-based metal layer can have the thickness of about 0.2 μm, the titanium-based metal layer can have the thickness of about 0.1 μm, and the aluminum layer or the gold layer can have the thickness of about 3.0 μm. In FIG. 1, the gate electrode 7 has a recess corresponding to a recess of the p conductivity type gate region 6. Alternatively, the recess of the p conductivity type gate region 6 can be filled with the gate electrode 7 so that a surface of the gate electrode 7 can be flattened.

A source electrode 8 is formed on the n conductivity type source region 4a, and a drain electrode 9 is formed on the n conductivity type drain region 4b. For example, the source electrode 8 and the drain electrode 9 can be made of the same material as the gate electrode 7.

In this way, the JFET is formed in the SiC semiconductor device. Although not shown in the drawings, the electrodes are electrically insulated from each other by an interlayer dielectric film and a protection film such as a silicon oxide film and a silicon nitride film.

The JFET formed in the SiC semiconductor device operates as follows. When a gate voltage is not applied to the gate electrode 7, the n conductivity type channel layer 3 pinches off due to a depletion layer extending from the p conductivity type gate region 6 through the n conductivity type channel layer 3 (and a depletion layer extending from the p conductivity type buffer layer 2 through the n conductivity type channel layer 3). Then, when the gate voltage is applied to the gate electrode 7, the depletion layer extending from the p conductivity type gate region 6 is reduced. As a result, a channel region is formed in the n conductivity type channel layer 3, and electric current flows between the source electrode 8 and the drain electrode 9 through the channel region. Thus, the JFET can act as a normally-off mode device.

The p conductivity type gate region 6 is formed in the recess 4c through the i-type sidewall layer 5. In such an approach, there is no need to form an additional p conductivity type layer, which has a lower impurity concentration than the p conductivity type gate region 6, between the n conductivity type layer 4 and the p conductivity type gate region 6. Therefore, the width of the depletion layer extending through the n conductivity type channel layer 3 can be controlled by the p conductivity type gate region 6 that is in direct contact with the n conductivity type channel layer 3. Thus, as compared to when the additional p conductivity type layer is formed between the n conductivity type layer 4 and the p conductivity type gate region 6, the gate voltage applied to the gate electrode 7 can be reduced. Further, since the JFET can perform high speed switching, the SIC semiconductor device can be suitable for high frequency application.

The sidewall of the p conductivity type gate region 6 is electrically isolated from the n conductivity type layer 4 by the i-type sidewall layer 5. Since the i-type sidewall layer 5 is made of semi-insulating i-type SIC with a very low impurity concentration, a gate-source capacitance and a gate-drain capacitance can be reduced.

Further, the SIC substrate 1 is made of semi-insulating material. In such an approach, radio waves generated when the JFET operates can be absorbed by the SIC substrate 1. Therefore, the SIC semiconductor device can be suitable for high frequency application.

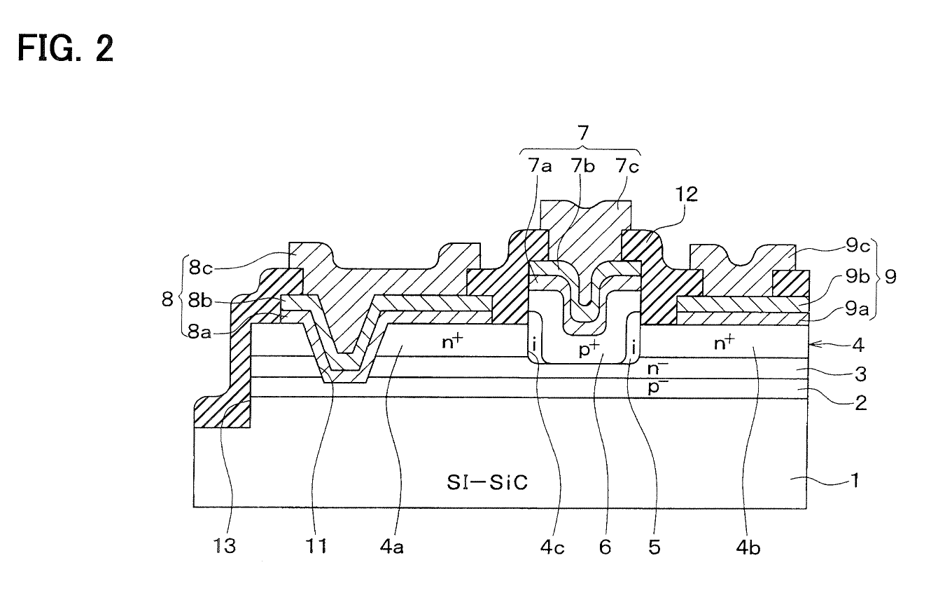

According to the first embodiment, the JFET has the p conductivity type buffer layer 2, and ground connection can be achieved by electrically connecting the p conductivity type buffer layer 2 to the source electrode 8. FIG. 2 illustrates a concrete example of the SIC semiconductor device having the JFET in which the p conductivity type buffer layer 2 is electrically connected to the source electrode 8.

As shown in FIG. 2, a recess 11 is formed at a position where the p conductivity type buffer layer 2 is electrically connected to the source electrode 8. The recess 11 penetrates the n conductivity type source region 4a and the p conductivity type buffer layer 2 and reaches the p conductivity type buffer layer 2. The source electrode 8 is elongated and thus located in the recess 11 so that the p conductivity type buffer layer 2 can be electrically connected to the source electrode 8 in the recess 11. The source electrode 8 is electrically insulated from the gate electrode 7 and the drain electrode 9 by an interlayer dielectric film 12 such as oxide film. In this way, the p conductivity type buffer layer 2 is electrically connected to the source electrode 8 so that the p conductivity type buffer layer 2 can be clamped to ground.

In the example shown in FIG. 2, each of the gate electrode 7, the source electrode 8, and the drain electrode 9 has a three-layer structure. The gate electrode 7 has a first layer 7a made of nickel-based metal, a second layer 7b made of titanium-based metal, and a third layer 7c made of aluminum layer or gold. The source electrode 8 has a first layer 8a made of nickel-based metal, a second layer 8b made of titanium-based metal, and a third layer 8c made of aluminum layer or gold. The drain electrode 9 has a first layer 9a made of nickel-based metal, a second layer 9b made of titanium-based metal, and a third layer 9c made of aluminum layer or gold. It is noted that a recess 13 located further away from the JFET region than the source electrode 8 provides an isolation trench for isolating the JFET region from another region.

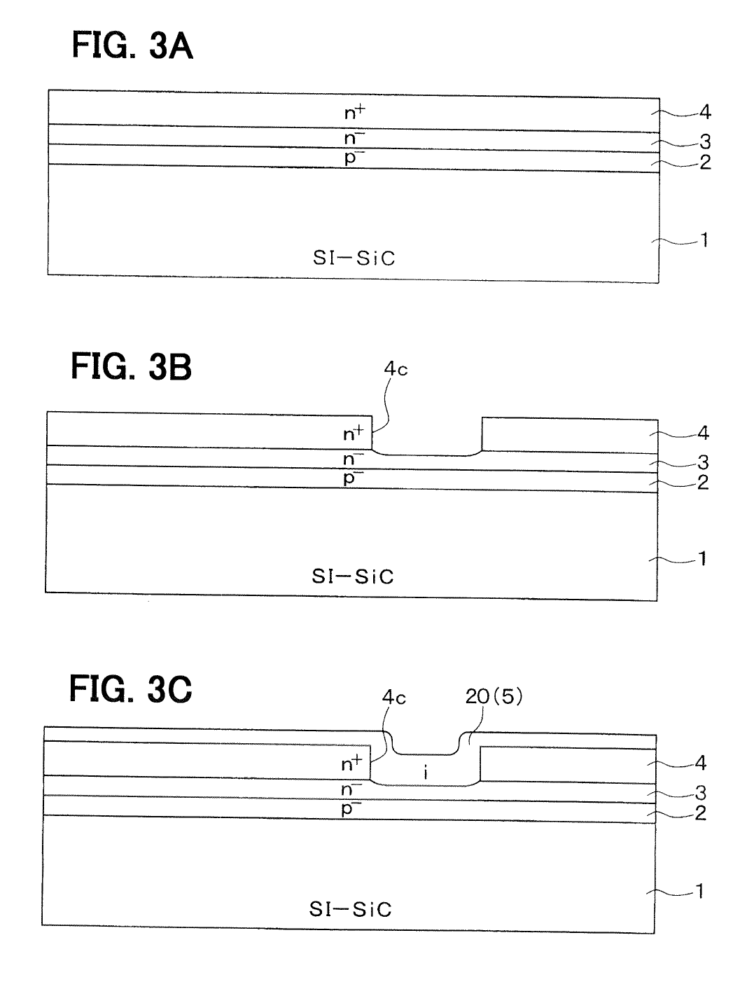

Next, a method of manufacturing the SIC semiconductor device shown in FIG. 2 is described below with reference to FIGS. 3A-3C, 4A-4C, 5A-5C, and 6A-6C.

In a process shown in FIG. 3A, the semi-insulating SiC substrate 1 having a main surface that is C-face plane is prepared, and the p conductivity type buffer layer 2 is epitaxially grown on the main surface of the SiC substrate 1 in such a manner that the p conductivity type buffer layer 2 has an impurity concentration of from about 1×10¹⁶cm⁻³ to about 1×10¹⁷cm⁻³ and a thickness of from about 0.2 μm to about 2.0 μm. For example, the p conductivity type buffer layer 2 can have the impurity concentration of about 1×10¹⁶cm⁻³ and have the thickness of about 0.4 μm. Then, the n conductivity type channel layer 3 is epitaxially grown on the p conductivity type buffer layer 2 in such a manner that the n conductivity type channel layer 3 has an impurity concentration of from about 1×10¹⁶cm⁻³ to about 1×10¹⁸cm⁻³ and a thickness of from about 0.1 μm to about 1.0 μm. For example, the n conductivity type channel layer 3 can have the impurity concentration of about 1×10¹⁷cm⁻³ and have the thickness of about 0.2 μm. Then, the n conductivity type layer 4 is epitaxially grown on the n conductivity type channel layer 3 in such a manner that the n conductivity type layer 4 has an impurity concentration of from about 5×10¹⁸cm⁻³ to about 1×10²⁰cm⁻³ and a thickness of from about 0.1 μm to about 1.0 μm. For example, the n conductivity type layer 4 can have the impurity concentration of about 2×10¹⁹cm⁻³ and the thickness of about 0.4 μm.

In a process shown in FIG. 3B, the recess 4c reaching the n conductivity type channel layer 3 is formed by partially etching the n conductivity type layer 4. Specifically, a metal mask (not shown) or an etching mask (not shown) such as a SiO₂ mask formed by photolithography is placed on the n conductivity type layer 4 to cover a region where the recess 4c is not formed. Then, anisotropic etching such as reactive ion etching (RIE) is performed by using the mask so that the recess 4c can be formed. In a case where the metal mask is used to form the recess 4c, the sidewall of the recess 4c can be inclined at an angle of from about 89° to about 90° with respect to a bottom of the recess 4c. In another case where the etching mask such as a SiO₂ mask is used to form the recess 4c, the sidewall of the recess 4c can be inclined at an angle of from about 85° to about 86° with respect to the bottom of the recess 4c. In each case, when the main surface of the substrate 1 is C-face (000-1) or Si-face (0001), the sidewall of the recess 4c is almost parallel to a-face plane.

In a process shown in FIG. 3C, an i-type layer 20 made of semi-insulating i-type SiC is epitaxially grown on the surface of the n conductivity type layer 4 and inside the recess 4c in such a manner that the i-type layer 20 have the background impurity concentration of from about 1×10¹¹cm⁻³ to about 1×10¹⁴cm⁻³. For example, the i-type layer 20 can have the background impurity concentration of about 1×10¹²cm⁻³.

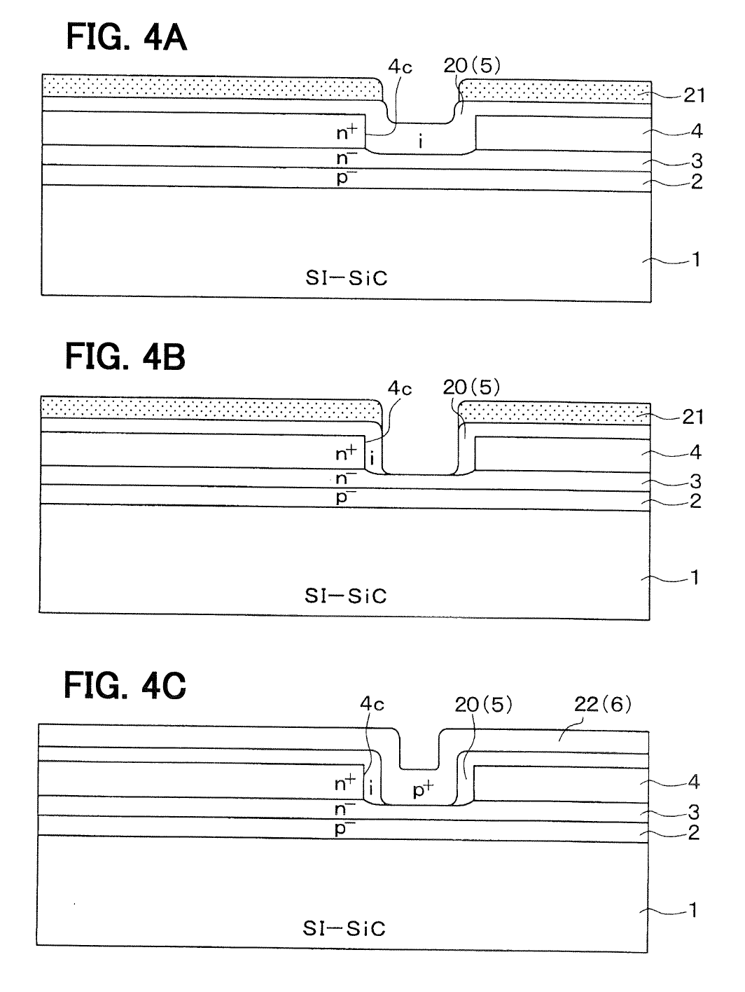

In a process shown in FIG. 4A, a mask 21 such as a low temperature oxide (LTO) film having an opening at a position, where the i-type sidewall layer 5 is not formed, is formed on a surface of the i-type layer 20.

In a process shown in FIG. 4B, anisotropic etching such as reactive ion etching (RIE) is performed on the condition that the i-type layer 20 is covered with the mask 21. Thus, in the recess 4c, the i-type layer 20 except on the sidewall of the recess 4c is removed so that the i-type sidewall layer 5 can be formed on the sidewall of the recess 4c.

In a process shown in FIG. 4C, after the mask 21 is removed, a p conductivity type layer 22 is epitaxially grown on the surface of the n conductivity type channel layer 3 and the surface of the i-type sidewall layer 5 in the recess 4c. The p conductivity type layer 22 provides the p conductivity type gate region 6 having an impurity concentration of from about 5×10¹⁸cm⁻³ to about 5×10¹⁹cm⁻³ and a thickness of from about 0.1 μm to about 0.5 μm. For example, the p conductivity type gate region 6 can have the impurity concentration of about 1×10¹⁹cm⁻³ and the thickness of about 0.4 μm.

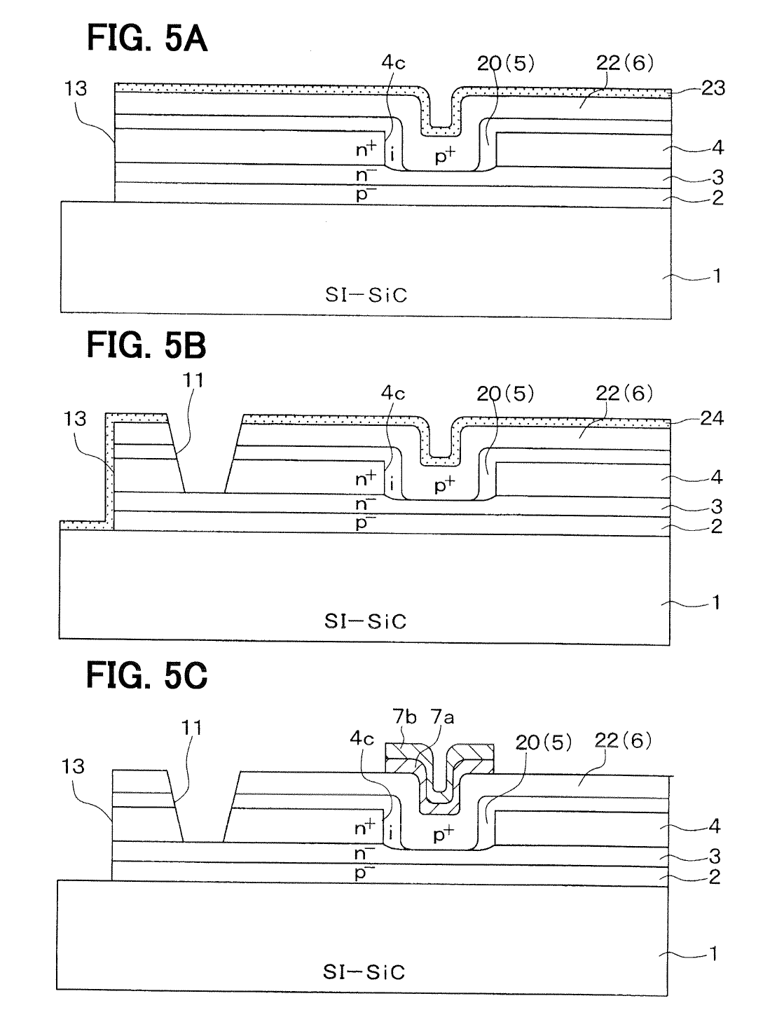

In a process shown in FIG. 5A, a mask 23 is placed on the surface of the p conductivity type gate region 6 except a region where the recess 13 is formed. Then, anisotropic etching such as reactive ion etching (RIE) is performed by using the mask 23 so that the recess 13 reaching the SiC substrate 1 can be formed.

In a process shown in FIG. 5B, after the mask 23 is removed, a mask 24 is placed inside the recess 13 and on the surface of the p conductivity type gate region 6 except a region where the recess 11 is formed. Then, anisotropic etching such as reactive ion etching (RIE) is performed by using the mask 24 so that the recess 11 can be formed.

Then, in a process shown in FIG. 5C, after the mask 24 is removed, a metal mask (not shown) or a mask (not shown) such as a SiO₂ mask is placed on the p conductivity type gate region 6 including the recess 11 to cover a region where the gate electrode 7 is not formed. Then, a nickel-based metal layer and a titanium-based metal layer are formed on the p conductivity type gate region 6 through the mask. Then, the mask is removed so that the first layer 7a and the second layer 7b of the gate electrode 7 can be formed by a lift-off method.

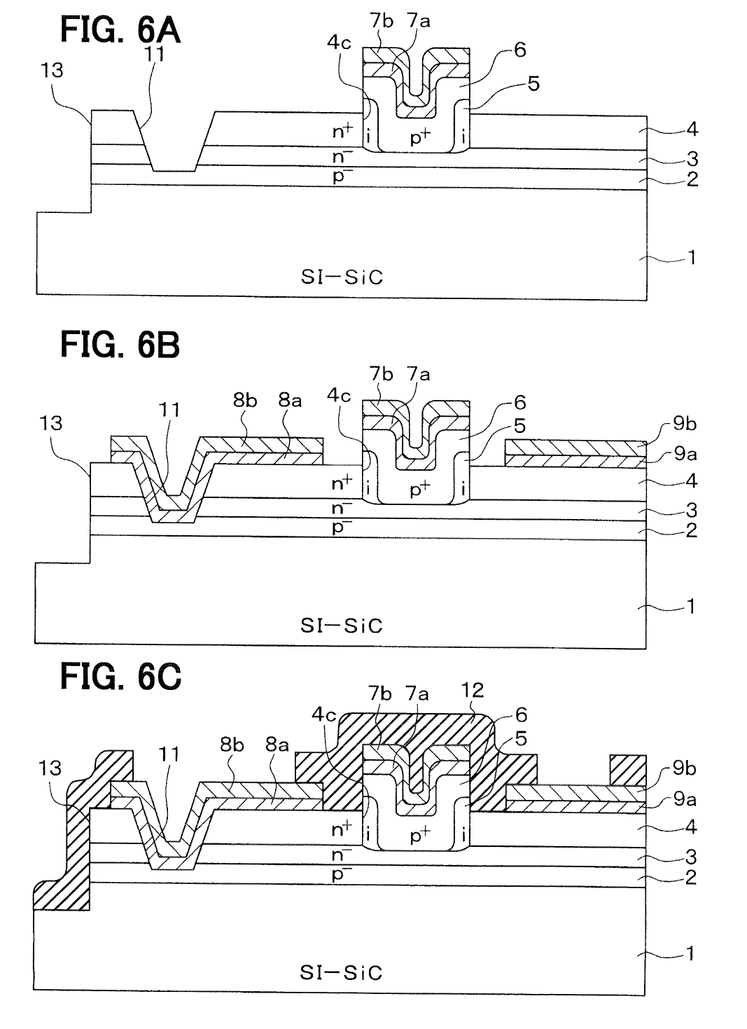

Then, in a process shown in FIG. 6A, anisotropic etching is performed by using the first layer 7a and the second layer 7b as a mask. As a result, the p conductivity type gate region 6 and the i-type sidewall layer 5 are patterned into a predetermined shape, and also the recess 11 is elongated to reach the p conductivity type buffer layer 2. Thus, the end surfaces (i.e., sidewalls) of the i-type sidewall layer 5, the p conductivity type gate region 6, and the gate electrode 7 are aligned with each other to from a continuous flat surface.

Then, in a process shown in FIG. 6B, a metal mask (not shown) or a mask (not shown) such as a SiO₂ mask is placed to cover a region where the source electrode 8 and the drain electrode 9 are not formed. Then, a nickel-based metal layer and a titanium-based metal layer are formed through the mask. Then, the mask is removed so that the first layers 8a, 9a and the second layers 8b, 9b of the source electrode 8 and the drain electrode 9 can be formed by a lift-off method. Then, thermal treatment can be performed as necessary. In such an approach, the first layers 7a, 8a, 9a of the gate electrode 7, the source electrode 8, and the drain electrode 9 is silicided (NiS₂) so that low resistance can be achieved.

Then, in a process shown in FIG. 6C, the interlayer dielectric film 12 such as a SiO₂ film is formed on the entire substrate surface. Then, the interlayer dielectric film 12 is patterned to form contact holes where the second layers 7b, 8b, 9b of the gate electrode 7, the source electrode 8, and the drain electrode 9 are partially exposed.

Then, the third layers 7c, 8c, 9c of the gate electrode 7, the source electrode 8, and the drain electrode 9 are formed on the second layers 7b, 8b, 9b, for example, by patterning an aluminum layer formed on the interlayer dielectric film 12 or by a gold plating method. In this way, the SiC semiconductor device shown in FIG. 2 can be manufactured.

As describe above, according to the first embodiment, the gate electrode 7 (i.e., the first layer 7a) is used as a mask to pattern the i-type sidewall layer 5 and the p conductivity type gate region 6. Thus, these are self-aligned with each other. If the gate electrode 7 is formed after patterning the p conductivity type gate region 6, there is a need to form the gate electrode 7 on a small p conductivity type gate region 6. Therefore, it is difficult to form the gate electrode 7 in such a manner that the i-type sidewall layer 5, the p conductivity type gate region 6, and the gate electrode 7 are aligned with each other. In contrast, according to the first embodiment, the i-type sidewall layer 5 and the p conductivity type gate region 6 are formed by using the gate electrode 7 as a mask. In such an approach, the i-type sidewall layer 5, the p conductivity type gate region 6, and the gate electrode 7 can be easily aligned with each other. Thus, a contact surface between the gate electrode 7 and the p conductivity type gate region 6 becomes large so that the gate electrode 7 can be surely, electrically connected to the p conductivity type gate region 6. Therefore, a gate resistance is reduced so that the JFET can perform high speed switching.

Furthermore, according to the first embodiment, the n conductivity type source region 4a, the n conductivity type drain region 4b, the n conductivity type channel layer 3, and the p conductivity type gate region 6 are formed by epitaxial growth not by ion implantation. In such an approach, gate leak current can be reduced.

### Second Embodiment

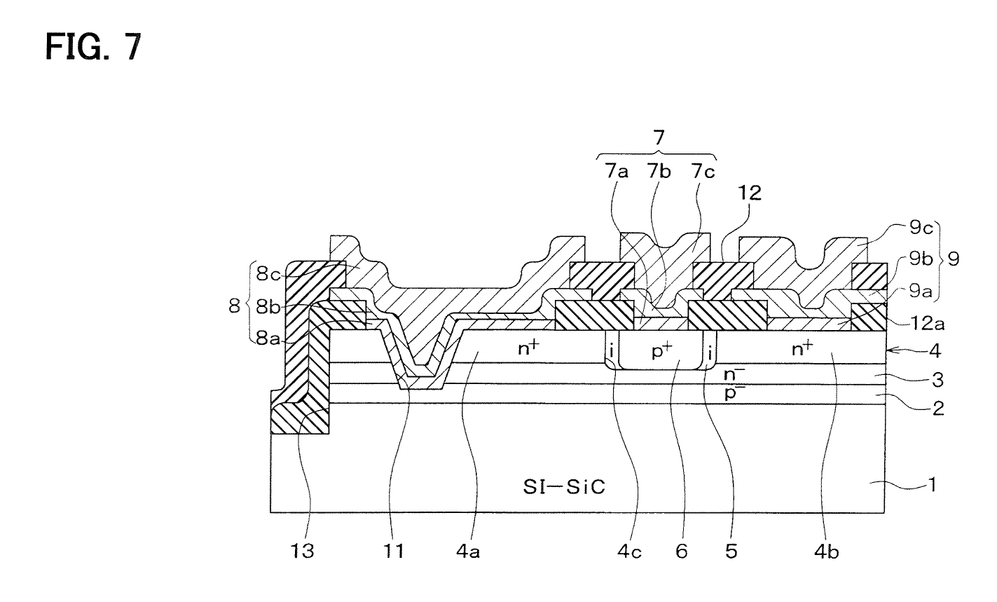

A second embodiment of the present invention is described below with reference to FIG. 7. FIG. 7 illustrates a cross-sectional view of a SiC semiconductor device having a JFET according to the second embodiment. The second embodiment differs from the first embodiment in the following point.

As shown in FIG. 7, according to the second embodiment, the end surfaces (i.e., sidewalls) of the i-type sidewall layer 5, the p conductivity type gate region 6, and the gate electrode 7 are not aligned with each other and do not from a continuous flat surface. Specifically, the gate electrode 7 has a width less than a width of the p conductivity type gate region 6 and is formed on the p conductivity type gate region 6. Even in such a structure, since the p conductivity type gate region 6 is formed in the recess 4c through the i-type sidewall layer 5, the same advantage as the first embodiment can be obtained.

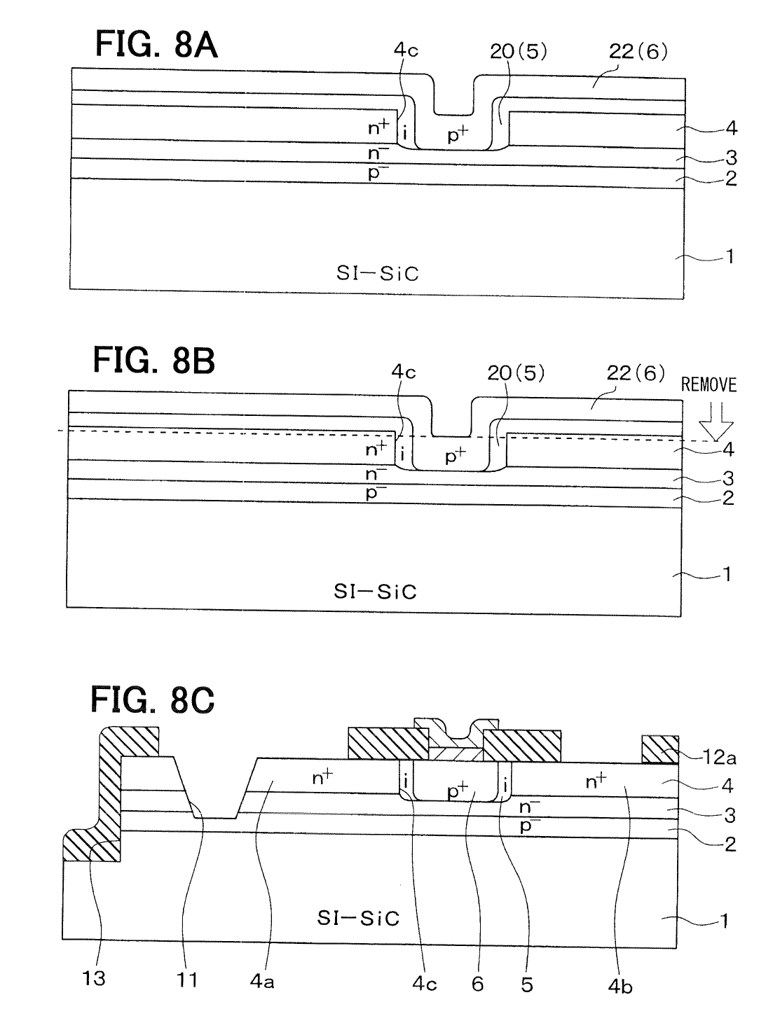

As mentioned previously, in the method of manufacturing the SiC semiconductor device according to the first embodiment, the patterning of the i-type sidewall layer 5 and the p conductivity type gate region 6 is performed by using the gate electrode 7 as a mask. In a method of manufacturing the SiC semiconductor device according to the second embodiment, the gate electrode 7 is formed after the i-type sidewall layer 5 and the p conductivity type gate region 6 are formed. The method of manufacturing the SiC semiconductor device according to the second embodiment is described below with reference to FIGS. 8A-8C.

Firstly, the manufacturing processes shown in FIGS. 3A-3C and FIGS. 4A-4C are performed so that a structure shown in FIG. 8A can be obtained. Then, in a process shown in FIG. 8B, planarization such as chemical mechanical planarization (CMP) is applied to a surface of the structure to remove a portion of the structure above a broken line in FIG. 8A. As a result of the planarization, the p conductivity type layer 22 and the i-type layer 20 remain only in the recess 4c so that the p conductivity type gate region 6 and the i-type sidewall layer 5 can be formed.

Then, the manufacturing processes shown in FIGS. 5A and 5B are performed to form the recess 11 and the recess 13. Then, in a process shown in FIG. 8C, an interlayer dielectric layer 12a such as a SiO₂ layer is formed on the entire planarized surface. Then, the interlayer dielectric layer 12a is patterned to form a contact hole where the p conductivity type gate region 6 and the n conductivity type layer 4 are exposed. Then, after a metal mask (not shown) or a mask (not shown) such as a SiO₂ mask is placed to cover an unexposed surface of the p conductivity type gate region 6, a Ni-based metal layer and a Ti-based metal layer for the first layer 7a and the second layer 7b of the gate electrode 7 are formed through the mask. Then, the mask is removed so that the first layer 7a and the second layer 7b can be formed by lift-off process.

Then, manufacturing processes similar to those shown in FIGS. 6A-6C are performed so that the SiC semiconductor device shown in FIG. 7 can be manufactured. In this way, the SiC semiconductor device having the JFET with the i-type sidewall layer 5 can be manufactured.

As described above, according to the manufacturing method of the second embodiment, since the manufacturing process shown in FIG. 5C is not performed, the patterning of the p conductivity type gate region 6 and the i-type sidewall layer 5 using the gate electrode 7 as a mask is not performed. Therefore, the p conductivity type gate region 6 and the i-type sidewall layer 5 are not self-aligned, and it is difficult to form the gate electrode 7 as compared to the first embodiment.

In the method described above, both the first layer 7a and the second layer 7b are formed by a lift-off process. In an alternative method, after the first layer 7a is formed by a lift-off process in such a manner that the width of the first layer 7a can be greater than the width of the contact hole, thermal treatment is applied to the first layer 7a so that the first layer 7a can be silicided. Then, etching is performed to remove the un-silicided portion of the first layer 7a. In such an approach, the first layer 7a can remain on the p conductivity type gate region 6 so that self-alignment can be achieved.

### Third Embodiment

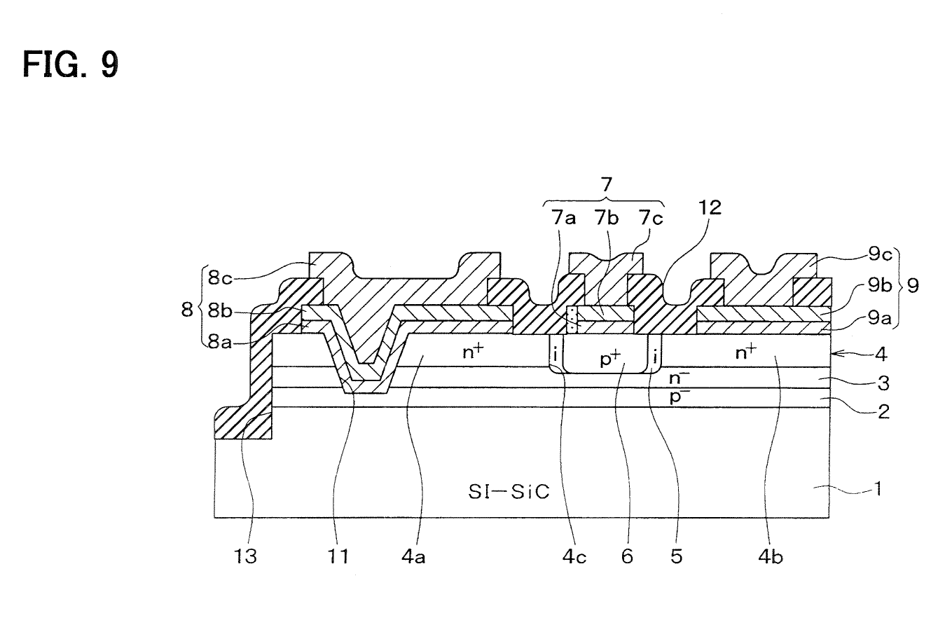

A third embodiment of the present invention is described below with reference to FIG. 9. FIG. 9 illustrates a cross-sectional view of a SiC semiconductor device having a JFET according to the third embodiment. The third embodiment differs from the second embodiment in the following point.

As shown in FIG. 9, according to the third embodiment, the gate electrode 7 is formed without the interlayer dielectric layer 12a. Even in such a structure, since the p conductivity type gate region 6 is formed in the recess 4c through the i-type sidewall layer 5, the same advantage as the first embodiment can be obtained.

Therefore, the SiC semiconductor device of the third embodiment can be manufactured in almost the same manner as the SiC semiconductor device of the second embodiment except that the first layer 7a and the second layer 7b of the gate electrode 7 are formed by lift-off process without the interlayer dielectric layer 12a.

### Fourth Embodiment

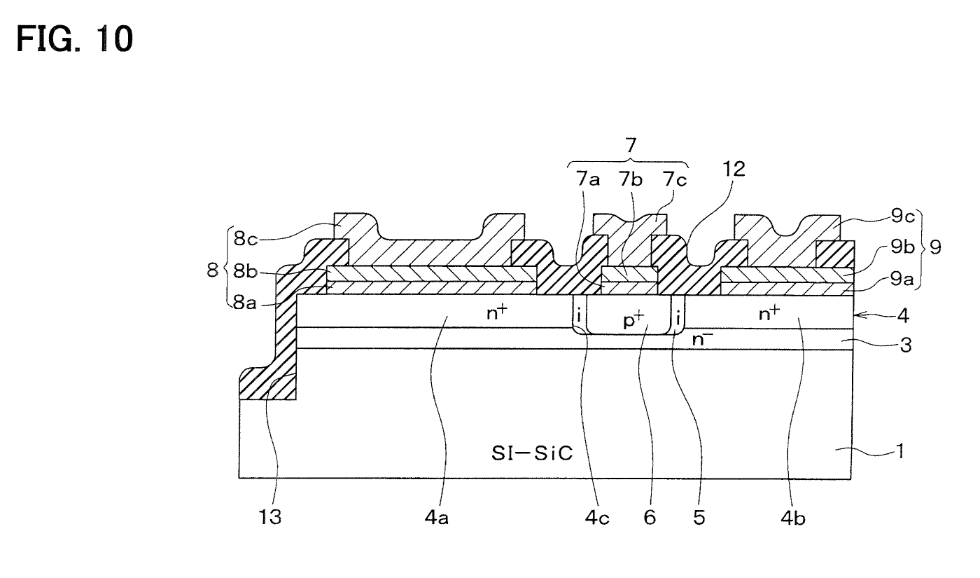

A fourth embodiment of the present invention is described below with reference to FIG. 10. FIG. 10 illustrates a cross-sectional view of a SiC semiconductor device having a JFET according to the fourth embodiment. The fourth embodiment differs from the third embodiment in the following point.

As shown in FIG. 10, according to the fourth embodiment, the n conductivity type channel layer 3 is directly formed on the main surface of the SiC substrate 1 without the p conductivity type buffer layer 2.

The SiC semiconductor device of the fourth embodiment can have almost the advantage as the SiC semiconductor device of the third embodiment. It is noted that since the SiC semiconductor device of the fourth embodiment does not have the p conductivity type buffer layer 2, a resistance to voltage breakdown of the SiC semiconductor device of the fourth embodiment is lower than a resistance to voltage breakdown of the SiC semiconductor device of the third embodiment.

The SiC semiconductor device of the fourth embodiment can be manufactured in almost the same manner as the SiC semiconductor device of the third embodiment. It is noted that since the SiC semiconductor device of the fourth embodiment does not have the p conductivity type buffer layer 2, the process for forming the p conductivity type buffer layer 2 and the process for forming the recess 11 through which the p conductivity type buffer layer 2 and the source electrode 8 are electrically connected together are omitted.

The p conductivity type buffer layer 2 of the first embodiment or the second embodiment can be removed in the same manner as the p conductivity type buffer layer 2 of the third embodiment.

### Fifth Embodiment

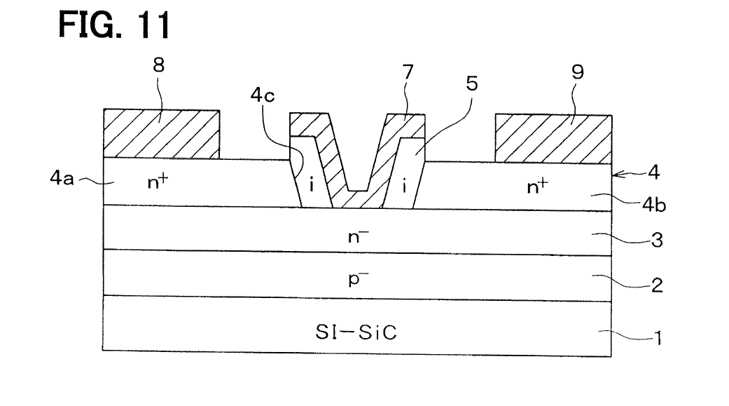

A fifth embodiment of the present invention is described below with reference to FIG. 11. FIG. 11 illustrates a cross-sectional view of a SiC semiconductor device having a metal semiconductor field effect transistor (MESFET) according to the fifth embodiment. The fifth embodiment differs from the first embodiment in the following points.

As can be seen by comparing FIG. 1 and FIG. 11, a difference between the first embodiment and the fifth embodiment is that the gate electrode 7 is directly formed on the surface of the n conductivity type channel layer 3 without the p conductivity type gate region 6. The gate electrode 7 forms a Schottky contact with the n conductivity type channel layer 3 to serve as a Schottky electrode. The gate electrode 7 is made of metal that can form a Schottky contact with n conductivity type SiC. The gate electrode 7 can have a thickness of from about 0.1 μm to about 1.0 μm. For example, the gate electrode 7 can have the thickness of about 0.2 μm.

The MESFET formed in the SiC semiconductor device operates as follows. When a gate voltage is not applied to the gate electrode 7 as a Schottky electrode, the n conductivity type channel layer 3 pinches off due to a depletion layer that extends from the gate electrode 7 through the n conductivity type channel layer 3 based on a difference in work function between the n conductivity type channel layer 3 and the gate electrode 7. Then, when the gate voltage beyond a Schottky barrier is applied to the gate electrode 7, a channel region is formed in the n conductivity type channel layer 3 so that electric current can flow between the source electrode 8 and the drain electrode 9 through the channel region. Thus, the MESFET can act as a normally-off mode device.

Since the gate electrode 7 is formed in the recess 4c through the i-type sidewall layer 5, the gate-source capacitance and the gate-drain capacitance can reduced.

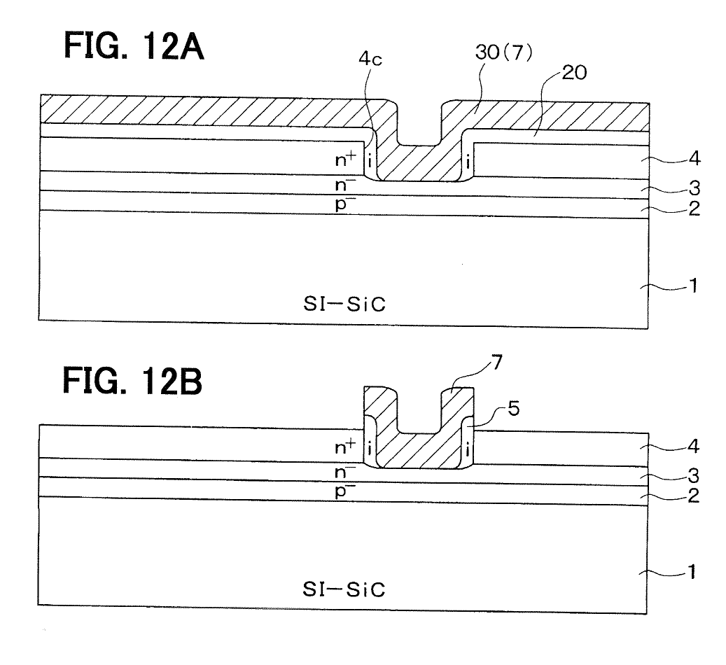

Next, a method of manufacturing the SiC semiconductor device having the MESFET according to the fifth embodiment is described below with reference to FIGS. 12A and 12B. The SiC semiconductor device of the sixth embodiment can be manufactured in almost the same manner as the SiC semiconductor device of the first embodiment.

Firstly, the manufacturing processes shown in FIGS. 3A-3C and FIGS. 4A and 4B are performed. Then, in a process shown in FIG. 12A, a metal layer 30 is formed on the surface of the n conductivity type channel layer 3 and the surface of the i-type layer 20 in the recess 4c so that the metal layer 30 can form a Schottky contact with the n conductivity type SiC. Then, the metal layer 30 and the i-type layer 20 are patterned into the gate electrode 7 and the i-type sidewall layer 5, respectively, by using a mask (not shown) having an opening at a position where the gate electrode 7 is formed. Then, the manufacturing processes shown in FIGS. 5A and 5B and FIGS. 6B and 6C are performed. Thus, the SiC semiconductor device having the MESFET shown in FIG. 11 can be manufactured.

The above method of manufacturing the SiC semiconductor device having the MESFET basically corresponds to the method of manufacturing the SiC semiconductor device having the JFET, shown in FIGS. 3A-6C, from which the process of forming the p conductivity type gate region 6 is removed. For example, after the i-type sidewall layer 5 is formed in such a manner that the width of the i-type sidewall layer 5 is greater than the width of the recess 4c, the gate electrode 7 is formed thereon. In such an approach, the gate electrode 7 can be formed easily. In this case, an unnecessary portion of the i-type layer 20 on the n conductivity type layer 4 can be removed in the process shown in FIG. 48, and the gate electrode 7 can be formed by a lift-off process.

### Modifications

The embodiment described above can be modified in various ways, for example, as follows.

In the embodiments, the source electrode 8 is in direct contact with the p conductivity type buffer layer 2 so that the source electrode 8 can be electrically connected to the p conductivity type buffer layer 2. Alternatively, the source electrode 8 can be electrically connected to the p conductivity type buffer layer 2 through a p conductivity type contact region that is located in the SiC substrate 1 or the p conductivity type buffer layer 2 at a position corresponding to the recess 11. In this case, the recess 11 is elongated to reach the p conductivity type contact region.

In the embodiments, the JFET and the MESFET have the n conductivity type channel layer 3 as a channel. That is, the JFET and the MESFET are configured as N-channel devices. Alternatively, the JFET and the MESFET can be configured as P-channel devices.

In the embodiments, the gate electrode 7, the source electrode 8, and the drain electrode 9 have a three-layer structure including a nickel-based metal layer, a titanium-based metal layer, and an aluminum layer or a gold layer. Alternatively, the gate electrode 7, the source electrode 8, and the drain electrode 9 can have a structure other than the three-layer structure. For example, the gate electrode 7, the source electrode 8, and the drain electrode 9 can have a multilayer structure of Ni/Ti/Mo/Au, Ti/Mo/Ni/Au, Ni/Mo/Ti, Ti/Mo/Ni, Ti/Mo, or Ni/Mo. For another example, the gate electrode 7, the source electrode 8, and the drain electrode 9 can have a single layer structure of Ti or Ni.

The semiconductor device according to the embodiments is based on SiC. Alternatively, the semiconductor device can be based on semiconductor other than SiC. For example, the semiconductor device can be based on silicon (Si). For another example, the semiconductor device can be based on wide-gap semiconductor such as gallium nitride (GaN), diamond, or aluminum nitride (AIN).

Such changes and modifications are to be understood as being within the scope of the present invention as defined by the appended claims.

What is claimed is:

1. A semiconductor device having a junction field-effect transistor (WET) comprising:
a semiconductor substrate having a main surface;
a first conductivity type semiconductor channel layer epitaxially grown on the main surface of the substrate;
a first conductivity type semiconductor layer epitaxially grown on a surface of the channel layer, the semiconductor layer having an impurity concentration greater than an impurity concentration of the channel layer;
a recess penetrating the semiconductor layer to divide the semiconductor layer into a source region and a drain region;
an i-type sidewall layer formed on a sidewall of the recess;
a second conductivity type gate region epitaxially grown on the surface of the channel layer in the recess and on a surface of the i-type layer, the gate region spaced by the i-type layer from the source region and the drain region;
a gate electrode electrically connected to the gate region;
a source electrode electrically connected to the source region; and
a drain electrode electrically connected to the drain region.

2. A semiconductor device having a metal-semiconductor field-effect transistor (MESFET) comprising:
a semiconductor substrate having a main surface;
a first conductivity type semiconductor channel layer epitaxially grown on the main surface of the substrate;
a first conductivity type semiconductor layer epitaxially grown on a surface of the channel layer, the semiconductor layer having an impurity concentration greater than an impurity concentration of the channel layer;
a recess penetrating the semiconductor layer to divide the semiconductor layer into a source region and a drain region;
an i-type sidewall layer formed on a sidewall of the recess;
a gate electrode formed on the surface of the channel layer in the recess and on a surface of the i-type sidewall layer to form a Schottky contact with the channel layer, the gate electrode spaced by the i-type sidewall layer from the source region and the drain region;
a source electrode electrically connected to the source region; and
a drain electrode electrically connected to the drain region.

3. The semiconductor device according to claim 1, wherein the substrate is a wide bandgap semiconductor substrate.

4. The semiconductor device according to claim 3, wherein the substrate is a silicon carbide substrate,
the i-type sidewall layer is made of i-type silicon carbide and epitaxially grown on the sidewall of the recess.

5. The semiconductor device according to claim 3, wherein an impurity concentration of the i-type sidewall layer ranges from 1×10¹¹cm⁻³ to 1×10¹⁴cm⁻³.

6. The semiconductor device according to claim 3, wherein a thickness of the i-type sidewall layer ranges from 0.1 μm to 1.0 μm.

7. The semiconductor device according to claim 3, wherein the impurity concentration of the channel layer ranges from 1×10¹⁶cm⁻³ to 1×10¹⁸cm⁻³.

8. The semiconductor device according to claim 3, wherein the impurity concentration of the gate region ranges from 5×10¹⁸cm⁻³ to 5×10¹⁹cm⁻³.

9. The semiconductor device according to claim 3, wherein the substrate is made of semi-insulating silicon carbide and has a resistivity ranging from 1×10¹⁰Ω·cm to 1×10¹¹Ω·cm.

10. The semiconductor device according to claim 3, further comprising:
a second conductivity type buffer layer located between the substrate and the channel layer, and
an impurity concentration of the buffer layer is less than the impurity concentration of the gate region.

11. A method of manufacturing a semiconductor device having a junction field-effect transistor (JFET), the method comprising:
preparing a semiconductor substrate;
forming a first conductivity type semiconductor channel layer on a main surface the substrate by epitaxial growth;
forming a first conductivity type semiconductor layer on a surface the channel layer by epitaxial growth in such a manner that the semiconductor layer has an impurity concentration greater than an impurity concentration of the channel layer;
forming a recess by anisotropic etching of the semiconductor layer in such a manner that the recess penetrates the semiconductor layer to divide the semiconductor layer into a source region and a drain region;
forming an i-type sidewall layer on a sidewall of the recess by epitaxial growth;
forming a second conductivity type gate region on the surface of the channel layer in the recess and on a surface of the i-type sidewall layer by epitaxial growth in such a manner that the gate region is spaced by the i-type sidewall layer from the source region and the drain region;
forming a gate electrode electrically connected to the gate region;
forming a source electrode electrically connected to the source region; and
forming a drain electrode electrically connected to the drain region.

12. The method according to claim according to claim 11, wherein
forming the i-type sidewall layer includes forming an i-type layer on a surface of the semiconductor layer including the sidewall and a bottom of the recess by epitaxial growth and removing the i-type layer on the bottom of the recess by etching;
forming the gate region includes forming a second conductivity type gate layer on the i-type layer, and
forming the gate electrode includes patterning at least partially the gate electrode, and
the gate layer and the i-type layer are patterned into the gate region by etching the gate layer and the i-type layer using the patterned gate electrode as a mask.

13. A method of manufacturing a semiconductor device having a metal-semiconductor field-effect transistor (MESFET), the method comprising:
preparing a semiconductor substrate;
forming a first conductivity type semiconductor channel layer on a main surface the substrate by epitaxial growth;
forming a first conductivity type semiconductor layer on a surface the channel layer by epitaxial growth in such a manner that the semiconductor layer has an impurity concentration greater than an impurity concentration of the channel layer;
forming a recess by anisotropic etching of the semiconductor layer in such a manner that the recess penetrates the semiconductor layer to divide the semiconductor layer into a source region and a drain region;
forming an i-type sidewall layer on a sidewall of the recess by epitaxial growth;
forming a gate electrode on the surface of the channel layer in the recess and on a surface of the i-type sidewall layer in such a manner that the gate electrode forms a Schottky contact with the channel layer and is spaced by the i-type sidewall layer from the source region and the drain region;
forming a source electrode electrically connected to the source region; and
forming a drain electrode electrically connected to the drain region.

14. The method according to claim according to claim 13, wherein
forming the i-type sidewall layer includes forming an i-type layer on a surface of the semiconductor layer including the sidewall and a bottom of the recess by epitaxial growth and removing the i-type layer on the bottom of the recess by etching;
forming the gate electrode includes patterning at least partially the gate electrode, and
the i-type layer is patterned into the i-type sidewall layer by etching the i-type layer using the patterned gate electrode as a mask.

15. The method according to claim 11, wherein
forming the recess includes placing a mask on the surface of the semiconductor layer, the mask having an opening at a position corresponding to the recess and being made of photoresist or silicon oxide, and
forming the recess further includes performing the anisotropic etching of the semiconductor layer using the placed mask in such a manner that the sidewall of the recess is inclined at an angle of from 85° to 86° with respect to a bottom of the recess.

16. The method according to claim 11, wherein
forming the recess includes placing a mask on the surface of the surface of the semiconductor layer, the mask having an opening at a position corresponding to the recess and being made of metal, and
forming the recess further includes performing the anisotropic etching of the semiconductor layer using the placed mask in such a manner that the sidewall of the recess is inclined at an angle of from 89° to 90° with respect to a bottom of the recess.
